(19) United States
(12) Patent Application Publication
(10) Pub. No.: US 2026/0101573 A1
(43) Pub. Date: Apr. 9, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Naoki KUNESHITA, Matsumoto-city (JP)

(73) Assignee: FUJI ELECTRIC CO., LTD., Kawasaki-shi (JP)

(21) Appl. No.: 19/403,709

(22) Filed: Nov. 28, 2025

Related U.S. Application Data
(63) Continuation of application No. PCT/JP2024/036912, filed on Oct. 16, 2024.

(30) Foreign Application Priority Data
Dec. 15, 2023 (JP) 2023-211737

(51) Int. Cl. H10D 84/00; H10D 8/00; H10D 8/01; H10D 12/00; H10D 12/01; H10D 62/10; H10D 62/53; H10D 64/27; H10D 84/01

(52) U.S. Cl. CPC H10D 84/161; H10D 8/045; H10D 8/422; H10D 12/038; H10D 12/481; H10D 62/124; H10D 62/53; H10D 64/311; H10D 84/0109

(57) ABSTRACT

A semiconductor device, including: a semiconductor substrate; a first semiconductor layer provided at a first surface of the semiconductor substrate; a plurality of first semiconductor regions selectively provided at a first surface of the first semiconductor layer; a plurality of trenches penetrating through the first semiconductor regions and the first semiconductor layer, and reaching the semiconductor substrate; a plurality of gate insulating films provided in the plurality of trenches, respectively; a plurality of gate electrodes provided in the plurality of trenches via the gate insulating films, respectively; an interlayer insulating film provided on the gate electrodes; a first electrode provided on the plurality of first semiconductor regions and the first semiconductor layer; a second electrode provided at a second surface of the semiconductor substrate; and a plurality of tetra ethoxy silane (TEOS) or spin-on-glass (SOG) films embedded in the plurality of gate electrodes in the plurality of trenches, respectively.

### CROSS REFERENCE TO RELATED APPLICATIONS

This is a continuation application of International Application PCT/JP2024/036912 filed on Oct. 16, 2024 which claims priority from a Japanese Patent Application No. 2023-211737 filed on Dec. 15, 2023, the contents of which are incorporated herein by reference.

### BACKGROUND OF THE INVENTION

### 1. Field of the Invention

Embodiments of the disclosure relate to a semiconductor device and a method of manufacturing a semiconductor device.

### 2. Description of the Related Art

Conventionally, a field effect transistor is known in which not a gate electrodes but an interlayer insulating film is formed on a gate oxide film at a bottoms of a groove, and the capacitance between the gate electrodes and a drain region may be reduced by an amount corresponding to the absence of the gate electrodes on the bottoms of the groove (see, for example, Japanese Laid-Open Patent Publication No. H9-181311).

### SUMMARY OF THE INVENTION

A semiconductor device according to an embodiment of the present disclosure includes: a semiconductor substrate of a first conductivity type, the semiconductor substrate having a first surface and a second surface opposite to each other; a first semiconductor layer of a second conductivity type, provided at the first surface of the semiconductor substrate, the first semiconductor layer having a first surface and a second surface opposite to each other, the second surface of the first semiconductor layer facing the semiconductor substrate; a plurality of first semiconductor regions of the first conductivity type, selectively provided in the first semiconductor layer, at the first surface of the first semiconductor layer; a plurality of trenches penetrating through the plurality of first semiconductor regions and the first semiconductor layer and reaching the semiconductor substrate; a plurality of gate insulating films provided in the plurality of trenches, respectively; a plurality of gate electrodes provided in the plurality of trenches via the plurality of gate insulating films, respectively; an interlayer insulating film provided on the plurality of gate electrodes; a first electrode provided on surfaces of the plurality of first semiconductor regions and the first surface of the first semiconductor layer; a second electrode provided at the second surface of the semiconductor substrate; and a plurality of tetra ethoxy silane (TEOS) films or spin-on-glass (SOG) films embedded in the plurality of gate electrodes in the plurality of trenches, respectively.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting a structure of a semiconductor device according to a first embodiment.

FIG. 2 is a flowchart depicting a procedure of forming gate electrodes in a method of manufacturing the semiconductor device according to the first embodiment.

FIG. 3 is a cross-sectional view schematically depicting formation of gate electrodes in the method of manufacturing the semiconductor device according to the first embodiment.

FIG. 4 is a cross-sectional view schematically depicting formation of the gate electrodes in the method of manufacturing the semiconductor device according to the first embodiment.

FIG. 5 is a cross-sectional view schematically depicting formation of the gate electrodes in the method of manufacturing the semiconductor device according to the first embodiment.

FIG. 6 is a cross-sectional view schematically depicting formation of the gate electrodes in the method of manufacturing the semiconductor device according to the first embodiment.

FIG. 7 is a cross-sectional view schematically depicting formation of the gate electrodes in the method of manufacturing the semiconductor device according to the first embodiment.

FIG. 8 is a cross-sectional view schematically depicting formation of the gate electrodes in the method of manufacturing the semiconductor device according to the first embodiment.

FIG. 9 is a cross-sectional view depicting a structure of a semiconductor device according to a second embodiment.

FIG. 10 is a flowchart depicting a procedure of forming the gate electrodes in the method of manufacturing the semiconductor device according to the second embodiment.

FIG. 11 is a cross-sectional view schematically depicting formation of the gate electrodes in the method of manufacturing the semiconductor device according to the second embodiment.

FIG. 12 is a cross-sectional view schematically depicting formation of the gate electrodes in the method of manufacturing the semiconductor device according to the second embodiment.

FIG. 13 is a cross-sectional view schematically depicting formation of the gate electrodes in the method of manufacturing the semiconductor device according to the second embodiment.

FIG. 14 is a cross-sectional view schematically depicting formation of the gate electrodes in the method of manufacturing the semiconductor device according to the second embodiment.

FIG. 15 is a cross-sectional view schematically depicting formation of the gate electrodes in the method of manufacturing the semiconductor device according to the second embodiment.

FIG. 16 is a cross-sectional view depicting a structure of a semiconductor device according to a third embodiment.

FIG. 17 is a flowchart depicting a procedure of forming the gate electrodes in the method of manufacturing the semiconductor device according to the third embodiment.

FIG. 18 is a cross-sectional view schematically depicting formation of the gate electrodes in the method of manufacturing the semiconductor device according to the third embodiment.

FIG. 19 is a cross-sectional view schematically depicting formation of the gate electrodes in the method of manufacturing the semiconductor device according to the third embodiment.

FIG. 20 is a flowchart depicting a procedure of forming gate electrodes in a conventional method of manufacturing a semiconductor device.

FIG. 21 is a cross-sectional view depicting an occurrence of slip defects in a conventional semiconductor device.

### DETAILED DESCRIPTION OF THE INVENTION

First, problems associated with the conventional techniques are discussed. In the conventional semiconductor device, since a polysilicon film is embedded in a trench, there is a problem in that a large stress is generated in the device, at a surface thereof due to expansion of the polysilicon film or the like caused by a subsequent high-temperature process, whereby warpage or distortion of the wafer occurs.

An overview of an embodiment of the present disclosure is described. In light of the problems described above, a semiconductor device according to the present disclosure has the following features. The semiconductor device includes a first semiconductor layer of a second conductivity type provided at a front surface of a semiconductor substrate of a first conductivity type; first semiconductor regions of the first conductivity type, selectively provided in the first semiconductor layer, at a first surface thereof opposite to a second surface thereof facing the semiconductor substrate; trenches penetrating through the first semiconductor regions and the first semiconductor layer and reaching the semiconductor substrate; gate electrodes provided in the trenches via gate insulating films; an interlayer insulating film provided on the gate electrodes; a first electrode provided at surfaces of the first semiconductor regions and the first semiconductor layer; and a second electrode provided at a back surface of the semiconductor substrate. In the trenches, TEOS films are embedded in the gate electrodes.

According to the above disclosure, the TEOS films are embedded in the gate electrodes in the trenches. The TEOS films may cancel residual stress of the polysilicon film. Therefore, warpage or distortion of the wafer due to stress such as thermal expansion of the polysilicon film embedded in the trenches may be suppressed, and warpage or slip defects in the wafer overall may be suppressed. In addition, high-order wafer in-plane distortion due to stress may be suppressed. As a result, variation of the characteristics of the semiconductor device may be reduced and the reliability may be improved.

In the semiconductor device according to the present disclosure, the TEOS films may be in contact with the semiconductor substrate through the gate insulating films at the bottoms of the trenches.

According to the above disclosure, each of the gate electrodes is divided at the bottom of the trench corresponding thereto, the Miller capacitance is reduced, and the switching speed is increased.

In the semiconductor device according to the present disclosure, the TEOS films may be provided between the gate electrodes and the interlayer insulating film.

In the semiconductor device according to the present disclosure, the trenches may be embedded with SOG films instead of the TEOS films.

According to the above disclosure, slits are formed when the trenches are embedded with the polysilicon film. The stress may be reduced by the slits as compared with the related art. The present disclosure may be applied to a configuration in which the stress due to the polysilicon film is small, for example, a configuration in which the trench interval is wide, whereby warpage and slip defects in the wafer overall may be suppressed. In addition, high-order wafer in-plane distortion due to stress may be suppressed.

In the semiconductor device according to the present disclosure, each of the TEOS films may have a width of 0.16 μm or more but not more than 0.28 μm.

In light of the problems described above, a method of manufacturing a semiconductor device according to the present disclosure has the following features. First, a first process of forming a first semiconductor layer of a second conductivity type at a front surface side of a semiconductor substrate of a first conductivity type is performed. Next, a second process of selectively forming first semiconductor regions of the first conductivity type in the first semiconductor layer, at a first surface thereof opposite to a second surface thereof facing the semiconductor substrate side is performed. Next, a third process of forming trenches penetrating through the first semiconductor regions and the first semiconductor layer and reaching the semiconductor substrate is performed. Next, a fourth process of forming an insulating film along inner walls of the trenches is performed. Next, a fifth process of embedding a polysilicon film so as to form slits in the trenches is performed. Next, a sixth process of etching back the polysilicon film to leave portions constituting gate electrodes in the trenches is performed. Next, a seventh process of removing the insulating film on the surfaces of the first semiconductor regions and the first semiconductor layer and leaving portion constituting gate insulating films in the trenches is performed. Next, an eighth process of performing a high-temperature heat treatment on the semiconductor substrate is performed. Next, a ninth process of embedded the slits with a TEOS film is performed. Next, a tenth process of forming an interlayer insulating film on the gate electrodes is performed. Next, an eleventh process of forming a first electrode on surfaces of the first semiconductor regions and the first semiconductor layer is performed. Next, a twelfth process of forming a second electrode at a back surface of the semiconductor substrate is performed.

In the method of manufacturing the semiconductor device according to the present disclosure, after the fifth process but before the sixth process, the method may further include a thirteenth process of embedding the slits with a positive resist and exposing the positive resist thereby leaving the positive resist at bottoms of the slits, and after the sixth process but before the seventh process, the method may further include a fourteenth process of removing the positive resist at the bottoms of the slits.

In light of the problems described above, a method of manufacturing a semiconductor device according to the present disclosure has the following features. First, a first process of forming a first semiconductor layer of a second conductivity type at a front surface of a semiconductor substrate of a first conductivity type is performed. Next, a second process of selectively forming a first semiconductor regions of the first conductivity type in the first semiconductor layer at a first surface thereof opposite to a second surface thereof facing the semiconductor substrate is performed. Next, a third process of forming trenches penetrating through the first semiconductor regions and the first semiconductor layer and reaching the semiconductor substrate is performed. Next, a fourth process of forming an insulating film along the inner walls of the trenches is performed. Next, a fifth process of embedding a polysilicon film so as to form slits in the trenches is performed. Next, a sixth process of depositing an SOG film so as to fill the slits is performed. Next, a seventh process of removing the SOG film and the insulating film on the surfaces of the first semiconductor regions and the first semiconductor layer and leaving portions constituting gate insulating films in the trenches is performed. Next, an eighth process of performing a high-temperature heat treatment on the semiconductor substrate is performed. Next, a ninth process of forming an interlayer insulating film on the gate electrodes is performed. Next, a tenth process of forming a first electrode at surfaces of the first semiconductor regions and the first semiconductor layer is performed. Next, an eleventh process of forming a second electrode at a back surface of the semiconductor substrate is performed.

Findings underling the present disclosure are discussed. Here, problems of the conventional semiconductor device are described. A semiconductor device in which a polysilicon diode for a temperature sensor or the like is provided, via an insulating layer, at a front surface of a semiconductor substrate such as a Si substrate (semiconductor chip) having an insulated gate bipolar transistor (IGBT) or a metal oxide semiconductor field effect transistor (MOSFET) having a trench structure, for example, is conventionally known.

While a conventional IGBT has a planar gate structure, a vertical trench structure has been developed to reduce ON voltage to reduce power consumption. As a result, the cell density may be greatly increased by providing the gates at sidewalls of the trenches and voltage drops in channel portions may be suppressed as compared with the planar type. In addition, since a junction field-effect transistor (JFET) portion of the channel portion does not exist in the trench structure, the voltage effect of the portion may also be reduced.

In a conventional manufacturing process of a semiconductor device, with an increase in the diameter of a crystal wafer, warpage or distortion of the wafer is likely to occur due to physical stress caused by the high-temperature process. For example, in an IGBT device or the like, a trench structure occupies a large portion of a wafer surface in an active region.

FIG. 20 is a flowchart depicting a procedure of forming gate electrodes in a conventional method of manufacturing a semiconductor device. The gate electrodes are formed as follows after the surface device structure is formed.

First, trenches are formed penetrating through the surface device structure by photolithography and etching (step S101). Next, a gate insulating film is formed along the inner walls of the trenches by, for example, thermal oxidation (step S102). Next, a polysilicon (poly-Si) film is formed on the front surface of the semiconductor wafer so as to be embedded in the trenches (step S103). Next, the polysilicon film is etched back, for example, thereby leaving portions constituting the gate electrodes in the trenches (step S104). Next, portions of the gate insulating film remaining at the front surface of the semiconductor wafer are removed (step S105). Thereafter, a high-temperature heat treatment is performed (step S106). Thus, a gate electrodes is formed.

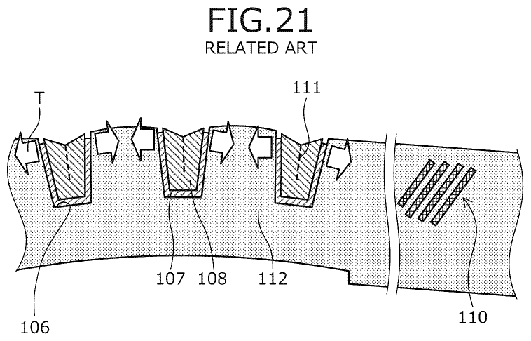

FIG. 21 is a cross-sectional view depicting an occurrence of slip defects in a conventional semiconductor device. In the formation of gate electrodes 108, since trenches 106 are embedded with a polysilicon film, a large stress T is generated in the surface side due to expansion or the like of the polysilicon film due to the subsequent high-temperature process. The stress T causes warpage or distortion of the wafer, and slip defects 110 are likely to occur. In FIG. 21, while the slip defects 110 are depicted in a guard ring outside the active region, the occurrence of the slip defects 110 is not limited to this location. For example, the slip defects 110 may occur between trenches 106. In FIG. 21, reference numerals 107, 111, and 112 denote gate insulating films, an interface to which a polysilicon film is bonded when the polysilicon film is implanted, and a silicon layer, respectively.

Here, a CZ crystal having a high oxygen concentration appears as a defect such as an OSF, and there is a concern about an influence on leakage characteristics. Therefore, in a power semiconductor chip such as an IGBT, an FZ wafer having few crystal defects is generally used in order to pass a large current in a vertical direction (cross-sectional direction).

However, since the FZ crystal has a low oxygen concentration, stress on the crystal tends to appear as slip defects. Therefore, when a non-uniform stress is applied to one surface of the wafer, the curvature of the wafer becomes non-uniform and when the wafer is suctioned and flattened by a vacuum chuck or the like of an exposure machine in a photolithography process, a local magnification of the wafer changes due to the non-uniform stress in the wafer surface, and a high-order wafer in-plane distortion (IPD) that cannot be eliminated only by position and rotation correction occurs.

As described above, in the conventional technique, slip defects, which are crystal defects, are generated due to the stress in the wafer, and a mark position, which is an origin of superposition of patterns, is shifted due to defective characteristics caused by the slip defects or distortion at the wafer surface, which causes deterioration in superposition accuracy. Conventionally, as a countermeasure for the slip defects, it is necessary to lower the temperature of the heat treatment, and as a countermeasure for improving the alignment accuracy, it is necessary to increase the number of strain amount measurement samplings for each wafer and to correct high-order deviations, which leads to a decrease in throughput. In addition, there are problems of an increase in characteristics defects and a decrease in reliability due to defects and misalignment.

Hereinafter, preferred embodiments of a semiconductor device and a method of manufacturing a semiconductor device according to the present disclosure that solves the above-described problems of the conventional semiconductor device are described in detail with reference to the accompanying drawings. In the present specification and the accompanying drawings, layers and regions prefixed with n or p mean that majority carriers are electrons or holes, respectively. Further, + and − appended to n and p mean that the impurity concentration is higher and lower, respectively, than layers and regions without + and −. In the following description of the embodiments and the accompanying drawings, the same components are denoted by the same reference numerals, and redundant description thereof will be omitted. Further, with consideration of variation in manufacturing, description indicating the same or equal may be within 5%.

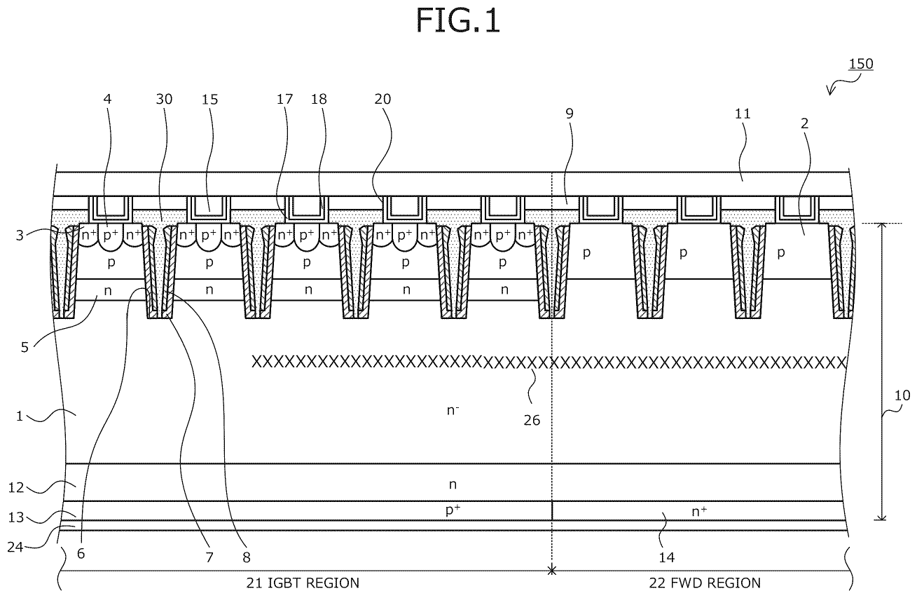

A semiconductor device and a method of manufacturing a semiconductor device according to a first embodiment solving the above-described problems is described below. FIG. 1 is a cross-sectional view depicting a structure of a semiconductor device according to a first embodiment. The structure of the semiconductor device according to the first embodiment will be described using the trenches type RC-IGBT 150 as an example. The semiconductor device according to the first embodiment depicted in FIG. 1 is an RC-IGBT 150 in which an IGBT having a trench structure and a diode connected in antiparallel to the IGBT are integrated on the same semiconductor substrate (semiconductor chip). The RC-IGBT 150 includes an active region, which is a region through which a current flows in an ON state, and an edge termination region surrounding the periphery of the active region, but FIG. 1 illustrates only the active region.

In the RC-IGBT 150, an IGBT region (transistor portion) 21 serving as an IGBT operation region and an FWD region (diode portion) 22 serving as a diode operation region are provided in parallel on a single semiconductor substrate having an active region.

In the semiconductor wafer (semiconductor substrate of the first conductivity type) 10 in the active region, an n-type storage layer 5 may be provided in an n⁻-type drift region 1, at a front surface (first main surface) thereof. The n-type storage layer 5 is a so-called carrier storage layer (CSL) that reduces spreading resistance of carriers. A p-type base region (first semiconductor layer of the second conductivity type) 2 is provided on the n-type storage layer 5, from the IGBT region 21 to the FWD region 22. The p-type base region 2 functions as a p-type anode region in the FWD region 22. Trenches (grooves) 6 penetrating through the p-type base region 2 and reaching the n⁻-type drift region 1 is provided. The trenches 6 are provided in the IGBT region 21 and the FWD region 22, and n⁺-type emitter regions (first semiconductor regions of the first conductivity type) 3 are provided on both sides of the IGBT region 21. The trenches 6 are arranged at predetermined intervals, for example, in a striped pattern in a plan view, and divide the p-type base region 2 into multiple regions (mesa portions). In the trenches 6, gate insulating films 7 are provided along inner walls of the trenches 6, and gate electrodes 8 are provided on the gate insulating films 7.

In the first embodiment, a TEOS (tetra ethoxy silane) film 30 is embedded in each of the gate electrodes 8 in the trenches 6. The TEOS films 30 may cancel the residual stress of the polysilicon film 32 (refer to FIG. 5) for forming the gate electrodes 8. Further, the TEOS films 30 are preferably provided between the gate electrodes 8 and the interlayer insulating film 9 described later. Each of the trenches 6 has a width of 0.8 μm or more but not more than 1.4 μm and a depth of 5 μm or more but not more than 6 μm. A width of each of the TEOS films 30 is about 0.2 μm, which is about ⅕ of each of the width of the trenches 6, for example, in a range of 0.16 μm or more but not more than 0.28 μm.

In the first embodiment, the TEOS films 30 penetrate the gate insulating films 7 at the bottoms of the trenches 6 and are in contact with the n⁻-type drift region 1. Thus, each of the gate electrodes 8 is divided at the bottom of the trench 6 corresponding thereto. In this case, there is an effect in that the Miller capacitance is reduced and the switching speed is increased (for example, refer to Ultra Low Miller Capacitance Trench-Gate IGBT with the Split Gate Structure Proceedings of the 27th International Symposium on Power Semiconductor Devices & IC's (May 10-14, 2015)).

In the IGBT region 21, the n⁺-type emitter regions 3 are selectively provided in each mesa portion in the p-type base region 2. The n⁺-type emitter regions 3 face the gate electrodes 8 across the gate insulating films 7 provided at the inner walls of the trenches 6. In each mesa portion, p⁺-type contact regions 4 may be provided. In this case, the n⁺-type emitter regions 3 and the p⁺-type contact regions 4 are in contact with each other. In the FWD region 22, the n⁺-type emitter regions 3 and the p⁺-type contact regions 4 are not provided in the p-type base region 2. The front surface electrode 11 is in contact with the n⁺-type emitter regions 3 via contact holes 20 and is electrically insulated from the gate electrodes 8 by the interlayer insulating film 9. Openings may be selectively provided in the n⁺-type emitter regions 3, and the front surface electrode 11 and the p-type base region 2 may be electrically connected to each other in the openings. When the p⁺-type contact regions 4 are provided, the front surface electrode 11 and the p⁺-type contact regions 4 may be electrically connected to each other. The front surface electrode 11 functions as an emitter electrode in the IGBT region 21 and functions as an anode electrode in the FWD region 22. Between the front surface electrode 11 and the interlayer insulating film 9, for example, a Ti film 17 and a TiN film 18 are provided as barrier metals for preventing diffusion of metal atoms from the front surface electrode 11 to the gate electrodes 8 side.

Alternatively, contact plugs may be embedded in the contact holes 20 formed in the interlayer insulating film 9. The contact plugs are formed of, for example, a metal film made of tungsten (W), which has high embeddability. The front surface electrode 11 is formed of an Al film or an Al alloy film such as Al—Si. When the cell pitch is wide, a structure in which the front surface electrode 11 is embedded in the contact holes 20 without forming the contact plugs may be employed. Hereinafter, the contact plugs or the front surface electrode 11 in the contact holes 20 is referred to as plug electrodes 15.

In the n⁻-type drift region 1, an n-type field stop (FS) layer 12 is provided in the semiconductor wafer 10, near a back surface thereof. The n-type FS layer 12 has a function of suppressing spreading of a depletion layer extending from a pn junction between the p-type base region 2 and the n⁻-type drift region 1 toward a p⁺-type collector region 13 described later at the time of OFF.

In the n⁻-type drift region 1, in the FWD region 22, a lifetime control region 26 may be provided at a position shallower than the n-type FS layer 12 from the front surface of the n⁻-type drift region 1. The lifetime control region 26 is formed by introducing a lattice defect (indicated by x) such as a vacancy (V) serving as a lifetime killer by irradiation with hydrogen (H) or helium (He). By forming the lifetime control region 26, loss in the device may be reduced. The lifetime control region 26 may extend to a vicinity of a boundary between the IGBT region 21 and the FWD region 22. The lifetime control region 26 may extend to the chip end of the edge termination region.

The p⁺-type collector region 13 is provided in the IGBT region 21 and an n⁺-type cathode region 14 is provided in the FWD region 22, in the n⁻-type drift region 1, at a position shallower than is the n-type FS layer 12 from a back surface (second main surface) of the n⁻-type drift region 1. The n⁺-type cathode region 14 is adjacent to the p⁺-type collector region 13. The back electrode 24 is provided on the surfaces of the p⁺-type collector region 13 and the n⁺-type cathode region 14. The back electrode 24 functions as a collector electrode in the IGBT region 21 and functions as a cathode electrode in the FWD region 22.

Next, a method of manufacturing the semiconductor device according to the first embodiment will be described. First, the n⁻-type drift region 1 is formed in the n⁻-type semiconductor wafer 10. The n⁻-type semiconductor wafer 10 constituting the n⁻-type drift region 1 may be prepared. The material of the semiconductor wafer 10 may be silicon (Si) or silicon carbide (SiC). Hereinafter, a case where the semiconductor wafer 10 is a silicon wafer will be described as an example.

Next, a process including photolithography and ion implantation as one set is repeatedly performed under different conditions to form a surface device structure including a MOS structure in the semiconductor wafer 10, at the front surface thereof. For example, first, the p-type base region 2, the n⁺-type emitter regions 3, and the p⁺-type contact regions 4 of the IGBT are formed (first process and second process). The p-type base region 2 is formed in the entire active region from the IGBT region 21 to the FWD region 22. The p-type base region 2 also serves as a p-type anode region in the FWD region 22. The n⁺-type emitter regions 3 and the p⁺-type contact regions 4 are selectively formed in the p-type base region 2 in the IGBT region 21.

A portion of the semiconductor wafer 10 other than the p-type base region 2, the n-type field stop (FS) layer 12 to be described later, the p⁺-type collector region 13, and the n⁺-type cathode region 14 constitutes the n⁻-type drift region 1. In the IGBT region 21, the n-type storage layer 5 may be formed between the n⁻-type drift region 1 and the p-type base region 2. The n-type storage layer 5 serves as a barrier for minority carriers (holes) in the n⁻-type drift region 1 when the IGBT is turned on, and has a function of accumulating minority carriers in the n⁻-type drift region 1.

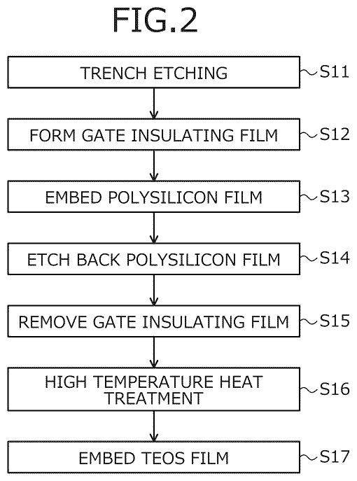

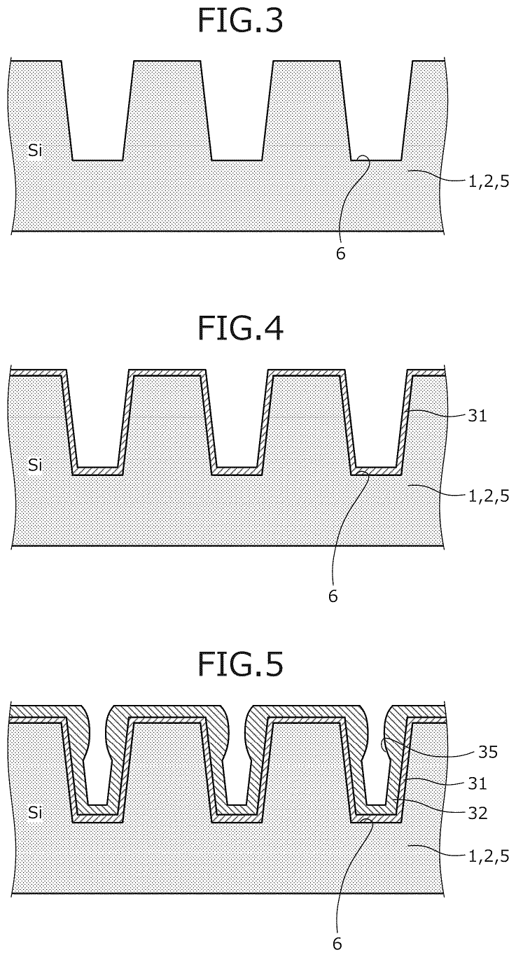

Next, the front surface of the semiconductor wafer 10 is thermally oxidized to form a field oxide film covering the front surface of the semiconductor wafer 10 in the edge termination region. The formation of the gate electrodes 8 having the trench structure according to the first embodiment will be described below. FIG. 2 is a flowchart depicting a procedure of forming the gate electrodes in the method of manufacturing the semiconductor device according to the first embodiment. FIGS. 3, 4, 5, 6, 7, and 8 are cross-sectional views schematically depicting formation of the gate electrodes in the method of manufacturing the semiconductor device according to the first embodiment.

First, by photolithography and etching, the trenches 6 are formed in the IGBT region 21 so as to penetrate through the n⁺-type emitter regions 3, the p-type base region 2, and the n-type storage layer 5 and reach the n⁻-type drift region 1 (step S11: third process). The state up to here is depicted in FIG. 3. When viewed from the front surface side of the semiconductor wafer 10, for example, the trenches 6 are arranged in a striped layout extending in a direction (direction of view in FIG. 1) orthogonal to a direction (lateral direction in FIG. 1) in which the IGBT region 21 and the FWD region 22 are arranged.

The trenches 6 are also formed in the FWD region 22 in the same layout as in the IGBT region 21. In the FWD region 22, the trenches 6 penetrate through the p-type base region 2 (p-type anode region) and reach the n⁻-type drift region 1. Next, the insulating film 31 is formed along the inner walls of the trenches 6 by, for example, thermal oxidation (step S12: fourth process). The state up to here is depicted in FIG. 4.

Next, a polysilicon (poly-Si) film 32 is formed at the front surface of the semiconductor wafer 10 so as to be embedded in the trenches 6 (step S13: fifth process). The state up to here is depicted in FIG. 5. Here, an embedding condition of the polysilicon film 32 is such that the trenches 6 are not completely filled with the polysilicon film 32. Thus, the trenches 6 are not completely embedded with the polysilicon film 32 and the slits 35 are formed. The width of each of the slits 35 is about 0.2 μm, which is about ⅕ of the width of each of the trenches 6, for example, in a range of 0.16 μm or more but less than 0.28 μm. When the width of each of the slits 35 is too narrow, the TEOS films 30 may not be embedded.

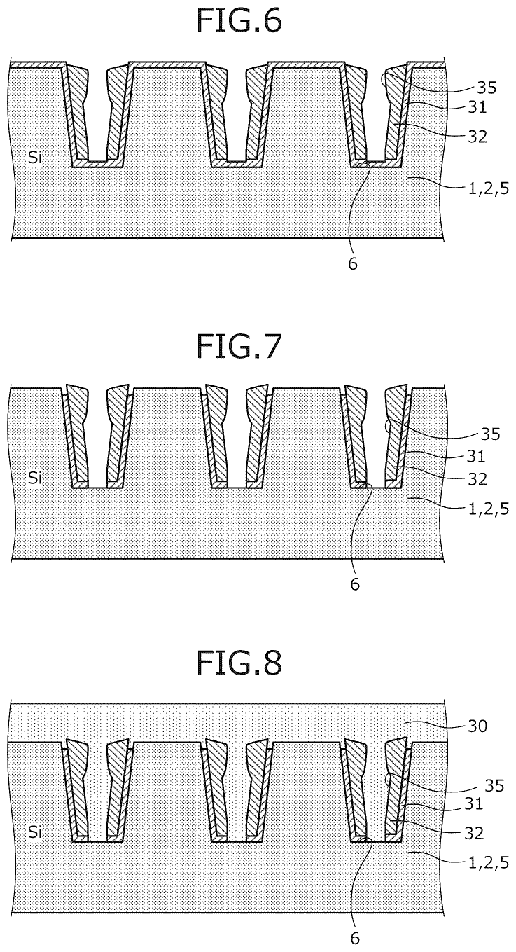

Next, the polysilicon film 32 is etched back, for example, so as to leave portions constituting the gate electrodes 8 in the trenches 6 (step S14: sixth process). The state up to here is depicted in FIG. 6. After this etching, channel ion implantation may be performed to the p-type base region 2.

When the etch-back is performed with the slits 35 formed, the polysilicon film 32 at the bottom of each of the trenches 6 is etched and thus, the polysilicon film 32 is divided at the bottom. In this case, each of the gate electrodes 7 is also divided at the bottoms of the trenches 6, and there is an effect that the Miller capacitance is reduced and the switching speed is increased.

Next, portions of the insulating film 31 remaining on the front surface of the semiconductor wafer 10 is removed (step S15: seventh process). The state up to here is depicted in FIG. 7. Portions of the insulating film 31 remaining in the trenches 6 becomes the gate insulating films 7. Thereafter, a high-temperature heat treatment is performed (step S16: eighth process). Next, the TEOS film 30 is embedded in the slits 35 (step S17: ninth process). The state up to here is depicted in FIG. 8. Through the process up to here, the gate electrodes 8 of the first embodiment is formed.

Here, it is known that the film stress of the polysilicon film 32 changes depending on the film formation temperature and the heat treatment after embedding. On the other hand, it is known that the film stress of the TEOS film 30 may also be adjusted by the embedding conditions such as the film formation temperature and the growth flow rate (for example, refer to Mihaela CARP; Violeta DEDIU; Florian PISTRITU; Edwin A. LASZLO; Ciprian ILIESCU, “Effective control of TEOS Effective control of TEOS-PECVD thin film depositions”, 2020 International Semiconductor Conference (CAS)). Thus, the embedding conditions of the TEOS films 30 are adjusted so as to cancel the residual stress of the polysilicon film 32 after the heat treatment, thereby canceling the residual stress of the polysilicon film 32.

As described above, in the first embodiment, when the polysilicon film 32 is embedded in the trenches 6, the polysilicon film 32 is embedded so as to form the slits 35, and the TEOS films 30 are embedded in the slits 35 and cancel the residual stress of the polysilicon film 32. Therefore, according to the method of manufacturing the semiconductor device according to the first embodiment, it is possible to suppress the warpage or distortion of the wafer due to stress such as the thermal expansion of the polysilicon film 32 caused by the embedding of the trenches 6, and to suppress the warpage or the slip defects in the wafer overall. In addition, high-order wafer in-plane distortion due to stress may be suppressed. As a result, variation of the characteristics of the semiconductor device may be reduced and the reliability may be improved.

The description returns to the method of manufacturing the semiconductor device. The p-type base region 2, the n⁺-type emitter regions 3, the p⁺-type contact regions 4, the trenches 6, the gate insulating films 7, and the gate electrodes 8 constitute MOS gates having a trench structure. After the gate electrodes 8 are formed, the n⁺-type emitter regions 3, the p⁺-type contact regions 4, and the n-type storage layer 5 may be formed. The n⁺-type emitter regions 3 may be disposed in at least one mesa region between adjacent trenches 6 (mesa region), and there may be a mesa region in which the n⁺-type emitter regions 3 are not disposed. Further, the n⁺-type emitter regions 3 may be selectively disposed at predetermined intervals in the direction in which the trenches 6 extend linearly in a plan view.

Next, after the surface device structure is formed, the interlayer insulating film 9 having, for example, two layers including a BPSG film and an HTO film is formed on the front surface of the semiconductor wafer 10 so as to cover the gate electrodes 8 (tenth process). Next, the interlayer insulating film 9 is patterned to form multiple contact holes 20 penetrating the interlayer insulating film 9 in a depth direction. The depth direction is a direction from the front surface to the back surface of the semiconductor wafer 10. The n⁺-type emitter regions 3 and the p⁺-type contact regions 4 are exposed in the contact holes 20, in the IGBT region 21. The p-type base region 2 is exposed in the contact holes 20, in the FWD region 22.

Next, a Ti film is uniformly formed in the contact holes 20 and on the surface of the interlayer insulating film 9 by a sputtering method. Next, a TiN film 18 is formed on the surface of the Ti film 17 by sputtering. Thus, a barrier metal 25 is stacked on the interlayer insulating film 9 and in the contact holes 20.

Next, at the surface of the TiN film 18 and in the contact holes 20, the plug electrodes 15 are embedded by, e.g., sputtering. Next, portions other than the Ti film 17, the TiN film 18, and portions constituting the plug electrodes 15 in the contact holes 20 are removed by etching to thereby form the plug electrodes 15 in the contact holes 20.

Next, an Al metal film serving as the front surface electrode 11 is formed by, for example, a sputtering method. The metal film may be formed of, for example, aluminum (Al-Si) containing silicon at a ratio of 1%. Next, the Al metal film is patterned. Next, the patterned Al metal film is annealed under a hydrogen atmosphere to form the front surface electrode 11.

The front surface electrode 11 is electrically connected to the p-type base region 2, the n⁺-type emitter regions 3, and the p⁺-type contact regions 4 in the IGBT region 21 and functions as an emitter electrode. The front surface electrode 11 is electrically connected to the p-type base region 2 in the FWD region 22 and functions as an anode electrode. The front surface electrode 11 may be electrically connected to the p-type base region 2 in a mesa region that is free of the n⁺-type emitter regions 3.

Next, the semiconductor wafer 10 is ground from the back surface to a position corresponding to a product thickness used for the semiconductor device. Next, a process including photolithography and ion implantation as one set is repeatedly performed under different conditions to form a back surface device structure in the semiconductor wafer 10, at the back surface thereof. For example, the n-type field stop (FS) layer 12, the n⁺-type cathode region 14, and the p⁺-type collector region 13 are formed.

The n⁺-type cathode region 14 is formed in the semiconductor wafer 10, at the ground back surface thereof spanning the entire back surface of the semiconductor wafer 10. The n-type field stop layer 12 is formed at a position deeper than is the n⁺-type cathode region 14 from the ground back surface of the semiconductor wafer 10. The n-type field stop layer 12 is formed at least from the IGBT region 21 to the FWD region 22. The n-type field stop layer 12 may be in contact with the n⁺-type cathode region 14.

Next, the p⁺-type collector region 13 is formed by changing a portion of the n⁺-type cathode region 14 corresponding to the IGBT region 21 to a p⁺-type by photolithography and ion implantation. That is, the p⁺-type collector region 13 is in contact with the n⁺-type cathode region 14 in the direction in which the IGBT region 21 and the FWD region 22 are arranged in a plan view. The p⁺-type collector region 13 may be in contact with the n-type field stop layer 12 in the depth direction.

Next, the p⁺-type collector region 13 and the n-type FS layer 12 are activated by a heat treatment (annealing). Next, a passivation film is formed on the front surface of the semiconductor wafer 10 so as to cover the edge termination region. Next, the passivation film is patterned to expose the emitter electrode, the anode electrode, and each electrode pad, Ni-P plating is grown on the emitter electrode and the anode electrode, and Au plating is grown thereon to form a surface electrode (eleventh process).

Next, a photoresist film (not depicted) having an opening corresponding to the FWD region 22 is formed on the front surface of the semiconductor wafer 10. The lifetime control region 26 may be formed by irradiating helium by a high acceleration energy and a deep range using the photoresist film as a mask (shielding film) to introduce (form) helium defects serving as a lifetime killer in the n⁻-type drift region 1.

Then, the photoresist film is removed by an ashing treatment (ashing). Next, the back electrode 24 is formed at the entire back surface of the semiconductor wafer 10 (twelfth process). The back electrode 24 is in contact with the p⁺-type collector region 13 and the n⁺-type cathode region 14. The back electrode 24 functions as a collector electrode and also functions as a cathode electrode. Thereafter, the semiconductor wafer 10 is cut (diced) into individual chips, thereby completing the RC-IGBT chip 150 (semiconductor chip).

As described above, according to the first embodiment, the TEOS film is embedded in the gate electrodes in the trenches. The TEOS films may cancel the residual stress of the polysilicon film. Thus, warpage or distortion of the wafer due to stress such as thermal expansion of the polysilicon film embedded in the trenches may be suppressed, and warpage or slip defects in the wafer overall may be suppressed. In addition, high-order wafer in-plane distortion due to stress may be suppressed. As a result, variation of the characteristics of the semiconductor device may be reduced and the reliability may be improved. Further, the TEOS film penetrates through the gate insulating films at the bottoms of the trenches and is in contact with the n⁻-type drift region. Thus, in each of the trenches, the gate electrode is divided at the bottom of the trench, the Miller capacitance is reduced, and the switching speed is increased.

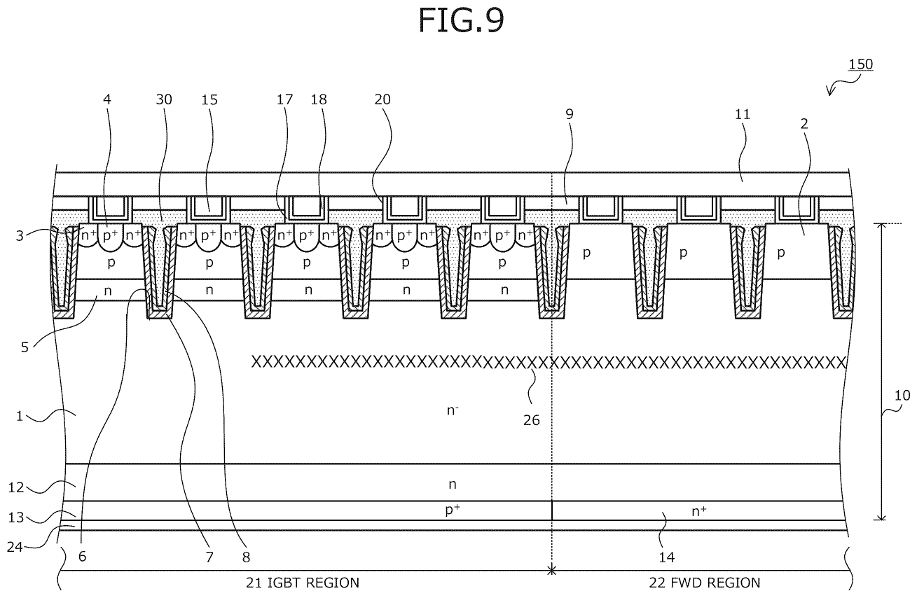

Next, a second embodiment is described. FIG. 9 is a cross-sectional view depicting a structure of a semiconductor device according to the second embodiment. In the second embodiment, the structure of the trenches 6 is different from that in the first embodiment. In the second embodiment, the TEOS films 30 are embedded in the gate electrodes 8 in the trenches 6 as in the first embodiment. However, the gate insulating films 7 and the gate electrodes 8 are provided at the bottoms of the trenches 6, and the TEOS films 30 do not penetrate through the gate insulating films 7 at the bottoms of the trenches 6. Also in the second embodiment, the residual stress of the polysilicon film 32 may be canceled by the TEOS films 30 as in the first embodiment. Further, the TEOS films 30 may be preferably provided between the gate electrodes 8 and the interlayer insulating film 9.

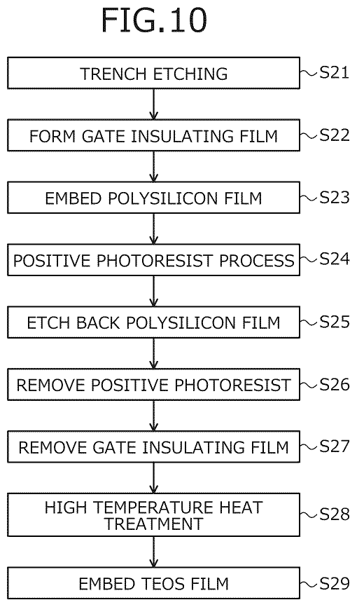

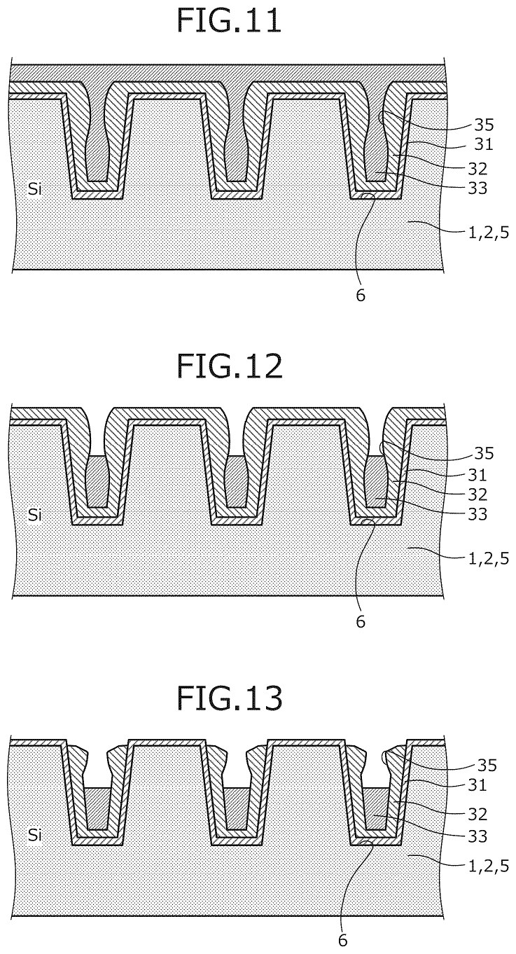

Next, a method of manufacturing the semiconductor device according to the second embodiment will be described. Since the method is the same as the method of manufacturing the semiconductor device according to the first embodiment except for the formation of the gate electrodes 8, the formation of the gate electrodes 8 will be described. FIG. 10 is a flowchart depicting a procedure of forming the gate electrodes in the method of manufacturing the semiconductor device according to the second embodiment. FIGS. 11, 12, 13, 14, and 15 are cross-sectional views schematically depicting formation of the gate electrodes in the method of manufacturing the semiconductor device according to the second embodiment.

First, by photolithography and etching, the trenches 6 are formed in the IGBT region 21 so as to penetrate through the n⁺-type emitter regions 3, the p-type base region 2, and the n-type storage layer 5 and reach the n⁻-type drift region 1 (step S21). Since the state up to here is the same as that of the first embodiment, description thereof is omitted here (refer to FIG. 3). Next, the insulating film 31 is formed along the inner wall of the trenches 6 by, for example, thermal oxidation (step S22). Since the state up to here is the same as that of the first embodiment, description thereof will be omitted (refer to FIG. 4).

Next, the polysilicon (poly-Si) film 32 is formed on the front surface of the semiconductor wafer 10 so as to be embedded in the trenches 6 (step S23). Since the state up to here is the same as that of the first embodiment, description thereof will be omitted here (refer to FIG. 5). Here, the embedding condition of the polysilicon film 32 is such that the trenches 6 are not completely embedded. Therefore, the trenches 6 are not completely embedded with the polysilicon film 32, and the slits 35 are formed.

Next, the slits 35 are embedded with the positive resist 33. 33 FIG. 11. Next, the positive resist 33 is exposed. In this case, since the positive resist 33 at the bottoms of the slits 35 is not exposed, a positive resist process in which the positive resist 33 is left at the bottoms of the slits 35 is performed (step S24: thirteenth process). The state up to here is depicted in FIG. 12.

Next, the polysilicon film 32 is etched back, for example, to leave portions to form the gate electrodes 8 in the trenches 6 (step S25). Since the positive resist 33 remains at the bottoms of the slits 35, the polysilicon film 32 of the slits 35 remains without being etched even when the etching back is performed. The state up to here is depicted in FIG. 13. After this etching, channel ion implantation may be performed in the p-type base region 2. In this case, since the positive resist 33 at the bottoms of the slits 35 serves as a mask for ion implantation, ions are not implanted at the bottoms of the trenches 6.

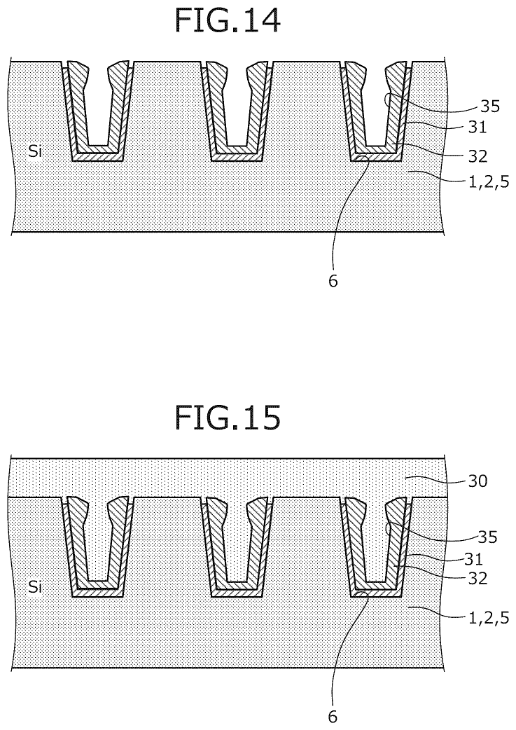

Next, the positive resist 33 is removed from the bottoms of the slits 35 (step S26: fourteenth process). Next, portions of the insulating film 31 remaining on the front surface of the semiconductor wafer are removed (step S27). The state up to here is depicted in FIG. 14. Portions of the insulating film 31 remaining in the trenches 6 becomes the gate insulating films 7. Thereafter, a high-temperature heat treatment is performed (step S28). Next, the TEOS film 30 is embedded (step S29). The state up to here is depicted in FIG. 15. At this time, as in the first embodiment, the embedding conditions of the TEOS films 30 are adjusted so as to cancel the residual stress of the polysilicon film 32 after the heat treatment, thereby canceling the residual stress of the polysilicon film 32. Through the processes up to here, the gate electrodes 8 of the second embodiment are formed.

As described above, according to the second embodiment, the TEOS films are embedded in the gate electrodes in the trenches. The TEOS films may cancel the residual stress of the polysilicon film. Thus, warpage or distortion of the wafer due to stress such as thermal expansion of the polysilicon film embedded in the trenches may be suppressed, and warpage or slip defects in the wafer overall may be suppressed. In addition, high-order wafer in-plane distortion due to stress may be suppressed. As a result, variation of the characteristics of the semiconductor device may be reduced and the reliability may be improved.

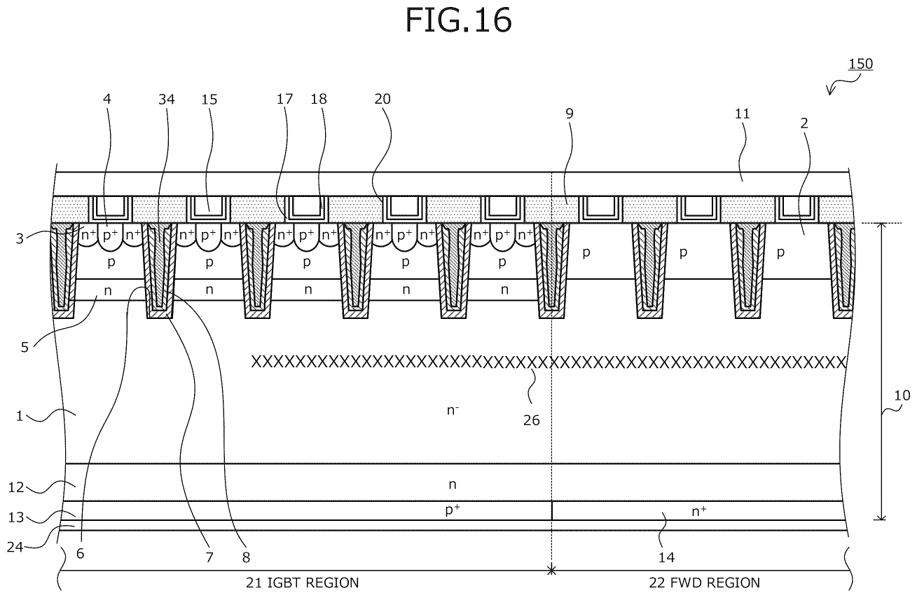

Next, a third embodiment will be described. FIG. 16 is a cross-sectional view depicting a structure of a semiconductor device according to the third embodiment. In the third embodiment, the structure of the trenches 6 is different from that in the first embodiment. In the third embodiment, unlike the first embodiment, spin on glass (SOG) films 34 are embedded in the gate electrodes 8 in the trenches 6. The SOG films 34 are preferably provided between the gate electrodes 8 and the interlayer insulating film 9. Each of the trenches 6 has a width of 0.8 μm or more but not more than 1.4 μm and a depth of 5 μm or more but not more than 6 μm The width of each of the SOG films 34 is about 0.2 μm, which is about ⅕ of the width of each of the trenches 6, for example, in a range of 0.16 μm or more but not more than 0.28 μm.

Unlike the TEOS films 30, the SOG films 34 cannot cancel the residual stress of the polysilicon film 32. However, in the third embodiment, the slits 35 are formed when the trenches 6 are embedded with the polysilicon film 32 (refer to FIG. 18). The SOG films 34 shrink by about 10% after the heat treatment, depending on the material. Therefore, by adjusting the width of the SOG films 34, the stress may be relaxed by offsetting the expansion of the polysilicon film 32. Further, the stress may be reduced by the slits 35 as compared with the related art. The present disclosure may be applied to a configuration in which the stress due to the polysilicon film 32 is small, for example, a configuration in which the interval of the trenches 6 is wide and the density of the trenches 6 is small, whereby warpage and slip defects in the wafer overall may be suppressed. In addition, high-order wafer in-plane distortion due to stress may be suppressed.

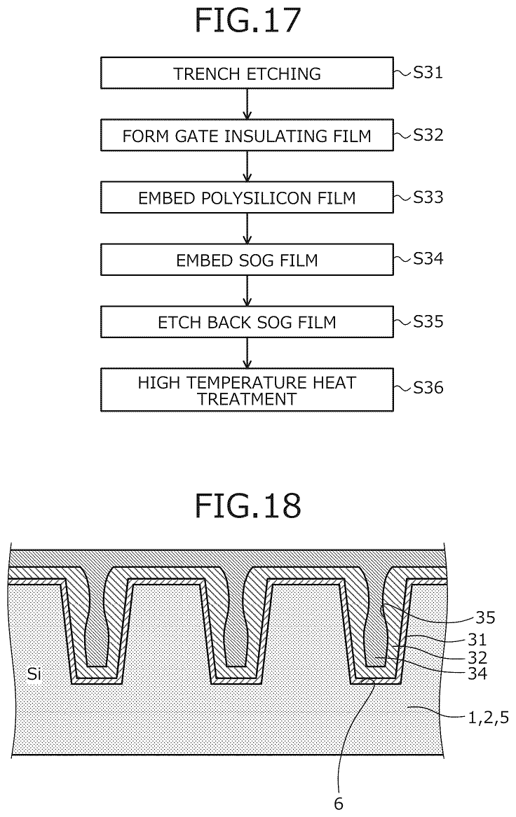

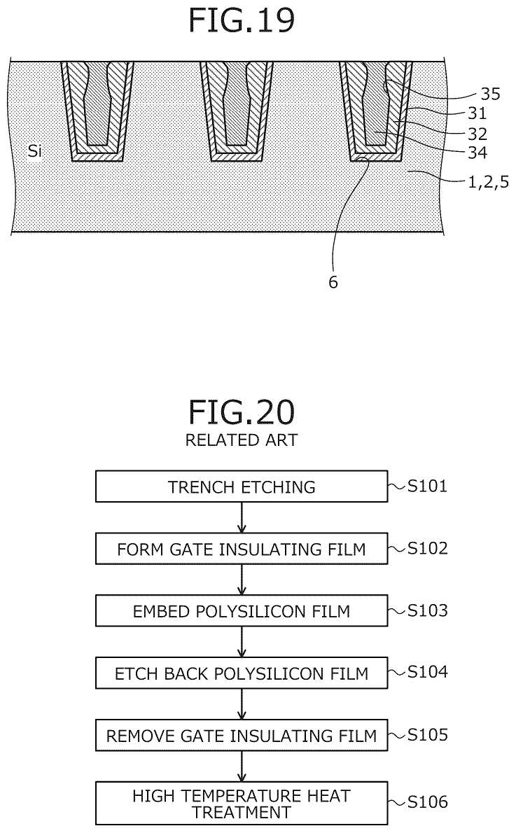

Next, a method of manufacturing the semiconductor device according to the third embodiment will be described. Since the method is the same as the method of manufacturing the semiconductor device according to the first embodiment except for the formation of the gate electrodes 8, the formation of the gate electrodes 8 will be described. FIG. 17 is a flowchart depicting a procedure of forming the gate electrodes in the method of manufacturing the semiconductor device according to the third embodiment. FIGS. 18 and 19 are cross-sectional views schematically depicting formation of the gate electrodes in the method of manufacturing the semiconductor device according to the third embodiment.

First, by photolithography and etching, the trenches 6 are formed in the IGBT region 21 so as to penetrate through the n⁺-type emitter regions 3, the p-type base region 2, and the n-type storage layer 5 and reach the n⁻-type drift region 1 (step S31). Since the state up to here is the same as that in the first embodiment, description thereof will be omitted here (refer to FIG. 3). Next, the insulating film 31 is formed along the inner walls of the trenches 6 by, for example, thermal oxidation (step S32). Since the state up to here is the same as that in the first embodiment, description thereof will be omitted here (refer to FIG. 4).

Next, the polysilicon (poly-Si) film 32 is formed at the front surface of the semiconductor wafer 10 so as to be embedded in the trenches 6 (step S33). Since the state up to here is the same as that in the first embodiment, description thereof will be omitted here (refer to FIG. 5). Here, the embedding condition of the polysilicon film 32 is such that the trenches 6 are not completely embedded. Therefore, the trenches 6 are not completely embedded with the polysilicon film 32, and the slits 35 are formed. Next, the SOG film 34 is deposited so as to be embedded in the slits 35 (step S34: sixth process). The state up to here is depicted in FIG. 18. Next, portions of the SOG film 34 on the device surface is removed by etch-back (step S35: seventh process). Thus, portions of the polysilicon film 32 and the insulating film 31 on the front surface of the semiconductor wafer 10 are removed, and the SOG film 34 is embedded in the slits 35. Thereafter, channel ion implantation may be performed to the p-type base region 2. Portions of the insulating film 31 remaining in the trenches 6 become the gate insulating films 7. Thereafter, a high-temperature heat treatment is performed (step S36). Through the processes up to here, the gate electrodes 8 of the third embodiment is formed.

As described above, according to the third embodiment, the SOG films are embedded in the gate electrodes in the trenches. In the third embodiment, the slits are formed when the trenches are embedded with the polysilicon film. Stress may be reduced by the slits as compared with the related art. The present disclosure may be applied to a configuration in which the stress due to the polysilicon film is small, for example, a configuration in which the trench interval is wide, and warpage and slip defects in the wafer overall may be suppressed. In addition, high-order wafer in-plane distortion due to stress may be suppressed.

In the foregoing, in the present disclosure, while a case where the MOS gate structure is formed in the silicon substrate, at the first main surface thereof has been described as an example, the present disclosure is not limited hereto, and the type of the semiconductor (for example, silicon carbide (SiC) or the like), the plane orientation of the substrate main surface, and the like may be variously changed. In addition, in the embodiments of the present disclosure, while a trench IGBT has been described as an example, the present disclosure is not limited hereto and is applicable to semiconductor devices having various configurations such as a MOS semiconductor device such as a trench MOSFET. Further, in the present disclosure, in the embodiments, while the first conductivity type is assumed to be an n-type and the second conductivity type is assumed to be a p-type, the present disclosure is similarly implemented when the first conductivity type is a p-type and the second conductivity type is an n-type.

According to the above disclosure, the TEOS films are embedded in the gate electrodes in the trenches. The TEOS films may cancel the residual stress of the polysilicon film. Thus, warpage or distortion of the wafer due to stress such as thermal expansion of the polysilicon film embedded in the trenches may be suppressed, and warpage or slip defects in the wafer overall may be suppressed. In addition, high-order wafer in-plane distortion due to stress may be suppressed. As a result, variation of the characteristics of the semiconductor device may be reduced and the reliability may be improved.

According to the semiconductor device and the method of manufacturing a semiconductor device according to the present disclosure, it is possible to suppress warpage or distortion of a wafer due to expansion of a polysilicon film or the like when the polysilicon film is embedded in trenches.

As described above, the semiconductor device and the method of manufacturing a semiconductor device according to the present disclosure are useful for high-voltage semiconductor devices used in power converting equipment, power supply devices for various industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, the semiconductor substrate having a first surface and a second surface opposite to each other;
a first semiconductor layer of a second conductivity type, provided at the first surface of the semiconductor substrate, the first semiconductor layer having a first surface and a second surface opposite to each other, the second surface of the first semiconductor layer facing the semiconductor substrate;
a plurality of first semiconductor regions of the first conductivity type, selectively provided in the first semiconductor layer, at the first surface of the first semiconductor layer;
a plurality of trenches penetrating through the plurality of first semiconductor regions and the first semiconductor layer and reaching the semiconductor substrate;
a plurality of gate insulating films provided in the plurality of trenches, respectively;
a plurality of gate electrodes provided in the plurality of trenches via the plurality of gate insulating films, respectively;
an interlayer insulating film provided on the plurality of gate electrodes;
a first electrode provided on surfaces of the plurality of first semiconductor regions and the first surface of the first semiconductor layer;
a second electrode provided at the second surface of the semiconductor substrate; and
a plurality of tetra ethoxy silane (TEOS) films or spin-on-glass (SOG) films embedded in the plurality of gate electrodes in the plurality of trenches, respectively.

2. The semiconductor device according to claim 1, wherein each of the plurality of TEOS films penetrates through a respective one of the plurality of gate insulating films at a bottom of a respective one of the plurality of trenches, and is in contact with the semiconductor substrate.

3. The semiconductor device according to claim 1, wherein each of the plurality of TEOS films is provided between a respective one of the plurality of gate electrodes and the interlayer insulating film.

4. The semiconductor device according to claim 1, wherein a width of each of the TEOS films is no less than 0.16 μm but not more than 0.28 μm.

5. A method of manufacturing a semiconductor device, the method comprising:
preparing a semiconductor substrate of a first conductivity type, the semiconductor substrate having a first surface and a second surface opposite to each other;
as a first process, forming a first semiconductor layer of a second conductivity type, at the first surface of the semiconductor substrate, the first semiconductor layer having a first surface and a second surface opposite to each other, the second surface of the first semiconductor layer facing the semiconductor substrate;
as a second process, selectively forming a plurality of first semiconductor regions of the first conductivity type, in the first semiconductor layer, at the first surface of the first semiconductor layer;
as a third process, forming a plurality of trenches penetrating through the plurality of first semiconductor regions and the first semiconductor layer and reaching the semiconductor substrate;
as a fourth process, forming an insulating film along inner walls of the plurality of trenches;
as a fifth process, embedding a polysilicon film so as to form a slit in each of the plurality of trenches;
as a sixth process, etching back the polysilicon film so as to leave a portion thereof in each of the plurality of trenches, thereby forming a gate electrode in each of the plurality of trenches;
as a seventh process, removing portions of the insulating film on surfaces of the plurality of first semiconductor regions and the first surface of the first semiconductor layer so as to leave a portion of the insulating film in each of the plurality of trenches, thereby forming a gate insulating film in each of the plurality of trenches;
as an eighth process, performing a high-temperature heat treatment to the semiconductor substrate;
as a ninth process, embedding a tetra ethoxy silane (TEOS) film in the slit in each of the plurality of trenches;
as a tenth process, forming an interlayer insulating film covering the gate electrode in each of the plurality of trenches;
as an eleventh process, forming a first electrode at the surfaces of the plurality of first semiconductor regions and the first surface of the first semiconductor layer; and
as a twelfth process, forming a second electrode at the second surface of the semiconductor substrate.

6. The method according to claim 5, further comprising:
as a thirteenth process, after the fifth process but before the sixth process, embedding a positive resist in the slit in each of the plurality of trenches and exposing the positive resist so as to leave the positive resist at a bottom of the slit; and
as a fourteenth process, after the sixth process but before the seventh process, removing the positive resist at the bottom of the slit.

7. A method of manufacturing a semiconductor device, the comprising:
preparing a semiconductor substrate of a first conductivity type, the semiconductor substrate having a first surface and a second surface opposite to each other;
as a first process, forming a first semiconductor layer of a second conductivity type, at the first surface of the semiconductor substrate, the first semiconductor layer having a first surface and a second surface opposite to each other, the second surface of the first semiconductor layer facing the semiconductor substrate;
as a second process, selectively forming a plurality of first semiconductor regions of the first conductivity type in the first semiconductor layer, at the first surface of the first semiconductor layer;
as a third process, forming a plurality of trenches penetrating through the plurality of first semiconductor regions and the first semiconductor layer and reaching the semiconductor substrate;
as a fourth process, forming an insulating film along an inner wall of each of the plurality of trenches;
as a fifth process, embedding a polysilicon film so as to form a slit in each of the plurality of trenches;
as a sixth process, depositing a spin-on-glass (SOG) film to be embedded in the slit in each of the plurality of trenches;
as a seventh process, removing portions of the SOG film and the insulating film on surfaces of the plurality of first semiconductor regions and the first surface of the first semiconductor layer, so as to leave a portion in each of the plurality of trenches, thereby forming a gate insulating film;
as an eighth process, performing a high-temperature heat treatment to the semiconductor substrate;
as a ninth process, forming an interlayer insulating film covering the gate electrode in each of the plurality of trenches;
as a tenth process, forming a first electrode on the surfaces of the plurality of first semiconductor regions and the first surface of the first semiconductor layer; and
as an eleventh process, forming a second electrode at the second surface of the semiconductor substrate.
